(19) United States
(12) Patent Application Publication
(10) Pub. No.: US 2026/0106112 A1
(43) Pub. Date: Apr. 16, 2026

(54) SUBSTRATE PROCESSING APPARATUS

(71) Applicant: SAMSUNG ELECTRONICS CO., LTD., Suwon-si (KR)

(72) Inventors: Kyoungmi CHOI, Suwon-si (KR); Kyoungwhan OH, Suwon-si (KR); Hakseon LEE, Suwon-si (KR)

(21) Appl. No.: 19/069,590

(22) Filed: Mar. 4, 2025

(30) Foreign Application Priority Data
Oct. 14, 2024 (KR) 10-2024-0139571

(51) Int. Cl. H01J 37/32; C23C 16/455; C23C 16/505; C23C 16/52

(52) U.S. Cl. CPC H01J 37/32174; C23C 16/45557; C23C 16/505; C23C 16/52; H01J 2237/3321

(57) ABSTRACT

Provided is a substrate processing apparatus including: a chamber, a stage in the chamber and configured to support a substrate, a first precursor supplier configured to provide a metal precursor into the chamber, a second precursor supplier configured to provide a reaction gas into the chamber, a first power supplier configured to apply first power having a first frequency into the chamber, a second power supplier configured to apply second power having a second frequency into the chamber, and a controller configured to control the first power supplier to apply the first power and the first precursor supplier to provide the metal precursor into the chamber, and the second power supplier to apply the second power and the second precursor supplier to provide the reaction gas into the chamber, in which the first frequency and the second frequency may be different.

### CROSS-REFERENCE TO RELATED APPLICATIONS

This application claims the benefit of Korean Patent Application No. 10-2024-0139571, filed on Oct. 14, 2024 in the Korean Intellectual Property Office, the disclosure of which is incorporated herein by reference in its entirety.

### FIELD

Example embodiments relate to a substrate processing apparatus.

### BACKGROUND

In semiconductor processes, a process of manufacturing various thin films may be included to process a substrate. The process of manufacturing a thin film may generally be performed through deposition. The deposition may be known as chemical vapor deposition (CVD), physical vapor deposition (PVD), and atomic layer deposition (ALD). In particular, plasma enhanced chemical vapor deposition (PECVD), which performs deposition using plasma, has been known.

Stresses may occur in a film deposited on the substrate according to the deposition conditions or environment. These stresses may subsequently lead to poor patterning of the substrate. This situation may also occur when performing the deposition using the PECVD to manufacture a hard mask, for example.

### SUMMARY

An aspect of the present disclosure provides a substrate processing apparatus capable of improving poor patterning of a substrate by allowing a substrate including a hard mask to maintain stability against a wide range of stress when manufacturing the hard mask.

Technical challenges of the present disclosure are not limited to the above-mentioned object(s). That is, other objects that are not mentioned may be clearly understood by those skilled in the art from the following description.

An aspect of the present disclosure provides a substrate processing apparatus including: a chamber, a stage in the chamber and configured to support a substrate; a first precursor supplier configured to provide a metal precursor into the chamber; a second precursor supplier configured to provide a reaction gas into the chamber; a first power supplier configured to apply first power having a first frequency into the chamber; a second power supplier configured to apply second power having a second frequency into the chamber; and a controller configured to control the first power supplier to apply the first power and the first precursor supplier to provide the metal precursor into the chamber, and the second power supplier to apply the second power and the second precursor supplier to provide the reaction gas into the chamber, in which the first frequency and the second frequency may be different.

Another aspect of the present disclosure provides a substrate processing apparatus including: a chamber, a stage in the chamber and configured to support a substrate; a first precursor supplier configured to provide a metal precursor into the chamber; a second precursor supplier configured to provide a reaction gas into the chamber; a first power supplier configured to apply first power having a first frequency into the chamber; a second power supplier configured to apply second power having a second frequency into the chamber; and a controller configured to control the first power supplier to apply the first power and the first precursor supplier to provide the metal precursor onto the substrate supported on the stage, and the second power supplier to apply the second power and the second precursor supplier to provide the reaction gas onto the substrate supported on the stage, in which the first frequency and the second frequency may be different.

Still another aspect of the present disclosure provides a substrate processing apparatus including: a chamber, a stage in the chamber and configured to support a substrate; a first precursor supplier configured to provide a metal precursor into the chamber; a second precursor supplier configured to provide a reaction gas into the chamber; a first power supplier configured to apply first power having a first frequency into the chamber; a second power supplier configured to apply second power having a second frequency into the chamber; and a controller configured to control the first power supplier to apply the first power and the first precursor supplier to provide the metal precursor onto the substrate supported on the stage, and the second power supplier to apply the second power and the second precursor supplier to provide the reaction gas onto the substrate supported on the stage, in which the controller may control the first power supplier, the first precursor supplier, the second power supplier, and the second precursor supplier such that the first power is applied and the metal precursor is provided onto the substrate supported on the stage, and then the second power is applied and the reaction gas is provided onto the substrate supported on the stage, in which the controller controls the second power supplier to apply the second power and the first precursor supplier to provide the metal precursor into the chamber while the substrate is not supported on the stage, and the first power supplier to apply the first power and the second precursor supplier to provide the reaction gas into the chamber while the substrate is not supported on the stage, in which the controller controls the first power supplier and the second power supplier such that a ratio (F2/F1) of the second frequency (F2) and the first frequency (F1) to be 1.5 or greater and 500 or less, and in which the controller controls the first power supplier and the second power supplier such that a magnitude of the second power is greater than that of the first power.

Detailed contents of other example embodiments are described in a detailed description and are illustrated in the drawings.

According to an aspect of the present disclosure, it is possible to provide a substrate processing apparatus capable of improving poor patterning of a substrate by allowing a substrate including a hard mask to maintain stability against a wide range of stress when manufacturing the hard mask.

The effects of the present disclosure are not limited to the above-mentioned effect(s), and other effects that are not mentioned may be clearly understood by those skilled in the art from the following description.

### BRIEF DESCRIPTION OF THE FIGURES

The drawings illustrated in the present disclosure are according to example embodiments, and a ratio of a width, depth, or height (or thickness) of each component may be for describing the present disclosure in detail, and these ratios may be different from the actual ones. In addition, each axis in coordinate systems illustrated in the drawings may be perpendicular to each other, and a direction pointed by an arrow may be a + or positive direction, and a direction (direction rotated by 180°) opposite to the direction pointed by an arrow may be a − or negative direction.

FIG. 1 is a cross-sectional view schematically illustrating a substrate processing apparatus according to example embodiments of the present disclosure.

FIGS. 2 to 4 are graphs showing power applied from a first power supplier and a second power supplier in a wave form according to example embodiments of the present disclosure.

FIGS. 5 and 6 are cross-sectional views schematically illustrating a substrate processing apparatus according to example embodiments of the present disclosure.

FIG. 7 is a flowchart for describing a method of performing a process of a substrate processing apparatus according to example embodiments of the present disclosure.

FIG. 8 is a flowchart for describing a method of performing a process of a substrate processing apparatus according to some other embodiments of the present disclosure.

### DETAILED DESCRIPTION

Prior to the detailed description of the present disclosure, it should be noted that terms or words used in this specification and claims may not be interpreted as limited to their ordinary or dictionary meanings. In addition, the terms or words may be interpreted to have meanings and concepts that conform to the technical idea of the present disclosure based on the principle that the Applicant may appropriately define the concept of terms to explain the present disclosure in the best way. The example embodiments described in this specification and the configurations illustrated in the drawings are merely illustrative example embodiments of the present disclosure and may not represent all of the technical ideas of the present disclosure. Accordingly, there may be various equivalents and modified examples that may replace the example embodiments at the time of filing of the present disclosure.

The same reference numbers or symbols described in each drawing attached to this specification may indicate parts or components that perform substantially the same function. For the convenience of description and understanding, the same reference numbers or symbols may be used in different example embodiments. In other words, even if components having the same reference numbers are illustrated in multiple drawings, all the multiple drawings may not mean an example embodiment.

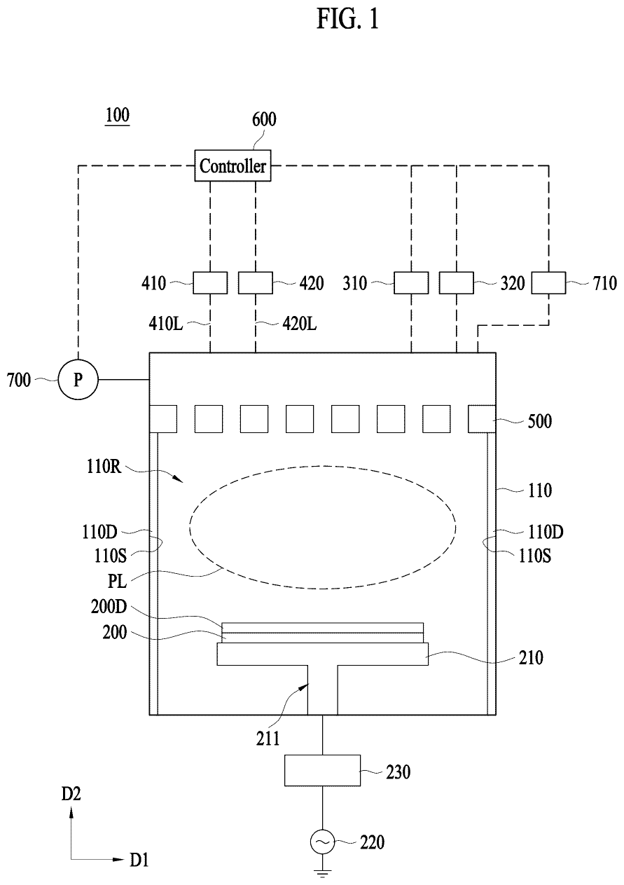

FIG. 1 is a cross-sectional view schematically illustrating a substrate processing apparatus 100 according to example embodiments of the present disclosure. The substrate processing apparatus 100 according to example embodiments of the present disclosure may be described based on a deposition apparatus for convenience of description. In example embodiments, the substrate processing apparatus 100 may be a deposition apparatus, and specifically, may be a plasma enhanced chemical vapor deposition (PECVD) apparatus. In example embodiments, the substrate processing apparatus 100 may be described based on the PECVD apparatus, but is not limited thereto.

In the present specification, a first direction D1 may be one of directions parallel to a surface of the substrate 200. A second direction D2 may be a direction intersecting the first direction D1. The second direction D2 may be, for example, one of the directions perpendicular to the surface of the substrate 200. In example embodiments, the first direction D1 and the second direction D2 may be perpendicular to each other.

In example embodiments, the substrate processing apparatus 100 may include a chamber 110 that accommodates a stage 210 for supporting the substrate 200. In example embodiments, the stage 210 may be electrically connected to a voltage application device 220 that applies a bias voltage to the substrate 200 and the stage 210. In example embodiments, the substrate processing apparatus 100 may include an impedance controller 230. The stage 210 may be electrically connected to the impedance controller 230.

In example embodiments, the chamber 110 may provide or define a substrate deposition space 110R which is a physical space where a substrate processing process, such as a deposition process, is performed. In addition, the chamber 110 may allow the substrate deposition space 110R to be sealed. In example embodiments, the chamber 110 may be electrically grounded.

In example embodiments, the substrate processing apparatus 100 may form a deposition film 200D (see FIG. 1) on the substrate 200. The substrate processing apparatus 100 may form the deposition film in an area other than the substrate 200.

In example embodiments, the substrate 200 may be, but is not particularly limited to, a silicon semiconductor substrate, a plastic substrate, a glass substrate, a compound semiconductor substrate, or a ceramic substrate.

In example embodiments, the substrate processing apparatus 100 may include a substrate support 211 that supports the stage 210. The substrate support 211 may be accommodated in the chamber 110. The substrate support 211 may fix a position of the substrate 200, may be raised and lowered along the second direction D2, and may rotate the substrate 200 with the second direction D2 as a rotation axis.

In example embodiments, the substrate processing apparatus 100 may include a showerhead 500. The showerhead 500 may include a plurality of holes disposed to allow fluid to move therethrough. The showerhead 500 may evenly supply or distribute plasma formed from a precursor, to the substrate deposition space 110R.

In example embodiments, the substrate processing apparatus 100 may include a first precursor supplier or first precursor supply 410 that provides a metal precursor into the chamber 110 and a second precursor supplier or second precursor supply 420 that provides a reaction gas into the chamber 110.

In example embodiments, the first precursor supplier 410 may include a passage 410L connected to the chamber 110, and the metal precursor may be introduced into the chamber 110 through a passage 410L. The first precursor supplier 410 may include a valve installed in the passage 410L, and the valve may open or close the passage 410L. Here, the valve may operate through an electrical signal from a controller 600, which will be described below.

In example embodiments, the second precursor supplier 420 may include a passage 420L connected to the chamber 110, and the reaction gas may be introduced into the chamber 110 through the passage 420L. The second precursor supplier 420 may include a valve installed in the passage 420L, and the valve may open or close the passage 420L. Here, the valve may operate through an electrical signal from the controller 600, which will be described below.

In example embodiments, the metal precursor may include a metal halide. The metal precursor may include a metal element, and the metal element may include one selected from the group consisting of, for example, titanium (Ti), tungsten (W), aluminum (Al), copper (Cu), tantalum (Ta), rubidium (Ru), molybdenum (Mo), platinum (Pt), nickel (Ni), tin (Sn), lead (Pb), and cobalt (Co). The halide material may include a halogen element, and the halogen element may include one selected from the group consisting of fluorine (F), chlorine (Cl), bromine (Br), and iodine (I). For example, the metal precursor may include one or more of TiCl₄, WF₆, WCl₆, WF₅, WCl₅, WBr₆, MoF₆, and MoCl₅. In example embodiments, the metal precursor may include TiCl₄.

In example embodiments, in some cases, the first precursor supplier 410 may provide a gas containing a semiconductor element into the chamber 110. The gas containing the semiconductor element may include one or more selected from the group consisting of, for example, silicon (Si) and germanium (Ge). The gas containing the semiconductor element may include, for example, SiH₄.

In example embodiments, the first precursor supplier 410 may provide the metal precursor to the substrate deposition space 110R at a flow rate of, but not particularly limited to, 0.1 sccm to 50 sccm, 0.5 sccm to 45 sccm, or 1 sccm to 40 sccm.

In example embodiments, the reaction gas may include at least one of nitrogen (N) and oxygen (O). For example, the reaction gas may include, but is not limited to, at least one selected from the group consisting of nitrogen gas (N₂), ammonia gas (NH₃), oxygen gas (O₂), and diborane (B₂H₆). In example embodiments, the reaction gas may include at least one selected from the group consisting of nitrogen gas (N₂) and ammonia gas (NH₃).

In example embodiments, the second precursor supplier 420 may provide the reaction gas to the substrate deposition space 110R at a flow rate of, but not limited to, 1,000 sccm.

In example embodiments, the substrate processing apparatus 100 may include a first power supplier or first power supply 310 that applies a first power having a first frequency into the chamber 110. The first power supplier 310 may include a power device and an impedance matcher. The power apparatus may apply, for example, radio frequency (RF) power. The impedance matcher may be a device that minimizes power loss due to an impedance difference between an input terminal and an output terminal of radio frequency (RF) power applied from the power device. The first power supplier 310 may apply first power that has the first frequency into the chamber 110 through the power device and the impedance matcher.

In example embodiments, the first power supplier 310 may apply the first power into the chamber 110, and the first precursor supplier 410 may provide the metal precursor into the chamber 110. That is, the substrate processing apparatus 100 may cause the first power supplier 310 to apply the first power into the chamber 110 while the first precursor supplier 410 provides the metal precursor into the chamber 110. In example embodiments, the first power supplier 310 may operate through an electrical signal from the controller 600, which will be described below. In example embodiments, when the first power supplier 310 applies the first power into the chamber 110, plasma may be formed from the metal precursor provided by the first precursor supplier 410. In example embodiments, the substrate processing apparatus 100 may form plasma from the metal precursor to form the deposition film 200D on the substrate 200. Here, the deposition film 200D may be a metal layer. In example embodiments, when the metal precursor is provided on the substrate 200 supported on the stage 210, the substrate processing apparatus 100 may form the plasma from the metal precursor to form a deposition film 110D on a surface 110S within the chamber.

In example embodiments, the substrate processing apparatus 100 may include a second power supplier or second power supply 320 that applies second power having a second frequency into the chamber 110. The second power supplier 320 may include the power device and the impedance matcher. The power device may apply RF power, for example. The second power supplier 320 may apply second power that has the second frequency into the chamber 110 through the power device and the impedance matcher.

In example embodiments, the second power supplier 320 may apply the second power into the chamber 110, and the second precursor supplier 420 may provide the reaction gas into the chamber 110. That is, the substrate processing apparatus 100 may cause the second precursor supplier 420 to provide the reaction gas into the chamber 110 while the second power supplier 320 applies the second power into the chamber 110. In example embodiments, the second power supplier 320 may operate through the electrical signal from the controller 600, which will be described below. In example embodiments, when the second power supplier 320 applies the second power into the chamber 110, the plasma may be formed from the reaction gas provided by the second precursor supplier 420. In example embodiments, the substrate processing apparatus 100 may form plasma from the reaction gas to perform one of oxidization and nitridation on the deposition film 200D formed on the substrate 200. For example, the metal layer formed on the substrate 200 may be oxidized or nitrided. In example embodiments, when the reaction gas is provided on the substrate 200 supported on the stage 210, the substrate processing apparatus 100 may form plasma from the reaction gas to oxidize or nitridize the deposition film 110D deposited on the surface 110S within the chamber.

In example embodiments, the substrate processing apparatus 100 may include a plasma area PL in which plasma exists inside the chamber 110. The plasma present in the plasma area PL may have passed through the showerhead 500.

In example embodiments, the substrate processing apparatus 100 may include the controller 600 that is directly or indirectly connected to the included components to control their operations, thereby performing the substrate processing process. Here, the direct connection may mean a connection by contact through a wire, and an indirect connection may mean a connection without contact through wireless communication or the like. If necessary, the component connected to the controller 600 may include a transceiver for transmitting and receiving data in the form of an electronic signal. The controller 600 may also include a transceiver for transmitting and receiving data in the form of an electronic signal as another component. The controller 600 may include a circuit configured to perform a process described herein. The controller 600 may include dedicated circuity or may include, for example, a central processing unit (CPU) chip, a graphic processing unit (GPU) chip, an application processor (AP) chip, an application specific integrated circuit (ASIC), or other processing chips.

In example embodiments, the controller 600 may control the first power supplier 310, the second power supplier 320, the first precursor supplier 410, and the second precursor supplier 420. In example embodiments, the controller 600 may control the first power supplier 310 to apply the first power, the first precursor supplier 410 to provide a metal precursor into the chamber 110, the second power supplier 320 to apply the second power, and the second precursor supplier 420 to provide a reaction gas into the chamber. In example embodiments, the controller 600 may control the first power supplier 310 to apply the first power into the chamber 110, and the second power supplier 320 to apply the second power into the chamber 110.

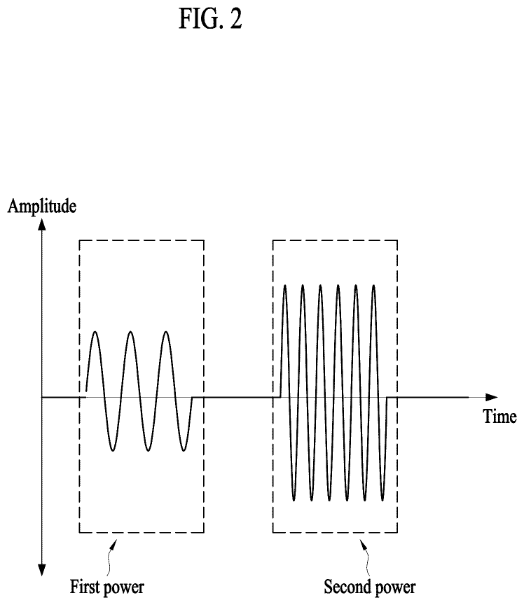

FIGS. 2 to 4 are graphs showing power applied from the first power supplier 310 and the second power supplier 320 in a wave form according to example embodiments of the present disclosure.

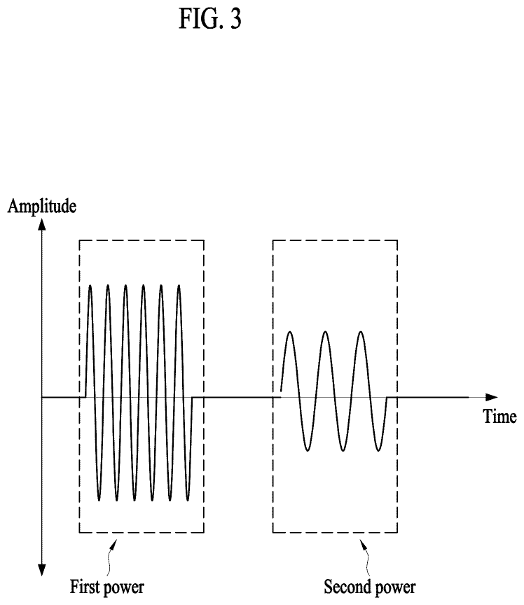

Referring to FIGS. 2 and 3, in example embodiments, the substrate processing apparatus 100 may apply the first power having the first frequency into the chamber 110 and then apply the second power having the second frequency into the chamber 110. In this case, the frequency may mean the number of times a periodic phenomenon, such as an oscillation of a current or voltage of the power, is repeated per unit time (for example, 1 second), and unless specifically limited herein, the unit may be Hertz (Hz). Specifically, the substrate processing apparatus 100 may allow the first precursor supplier 410 to provide the metal precursor into the chamber 110 while applying the first power having the first frequency into the chamber 110, thereby forming the metal layer on the substrate 200. The substrate processing apparatus 100 may allow the second precursor supplier 420 to provide the reaction gas into the chamber 110 while applying the second power having the second frequency into the chamber 110, thereby oxidizing or nitriding the metal layer formed on the substrate 200. In example embodiments, the first frequency may be different from the second frequency. In example embodiments, the controller 600 may control the first power to be applied and the metal precursor to be supplied into the chamber 110, and then the second power to be applied and the reaction gas to be supplied into the chamber 110.

Referring to FIG. 2, in example embodiments, the second frequency of the second power may be greater than the first frequency of the first power. Here, a ratio F₂/F₁ of the second frequency F₂ and the first frequency F₁ may be 1.5 or greater and 500 or less. In example embodiments, the first frequency F₁ may be in a range of 100 kilohertz (kHz) to 1000 kHz, and the second frequency F₂ may be in a range of 2 megahertz (MHz) to 40 MHz. In this case, the oxidized or nitrided metal layer manufactured through the substrate processing apparatus 100 may maintain stability against a wider range of stress.

Referring to FIG. 3, in example embodiments, the first frequency of the first power may be greater than the second frequency of the second power. Here, a ratio F₁/F₂ of the first frequency F₁ and the second frequency F₂ may be 1.5 or greater and 500 or less. In example embodiments, the first frequency F₁ may be in a range of 2 MHz to 40 MHz, and the second frequency F₂ may be in a range of 100 kHz to 1000 kHz. In this case, the oxidized or nitrided metal layer manufactured through the substrate processing apparatus 100 may have better uniformity.

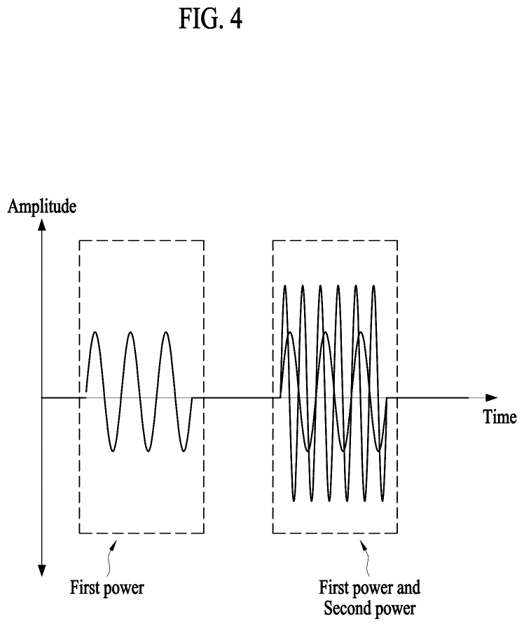

Referring to FIG. 4, in example embodiments, the substrate processing apparatus 100 may be configured such that there is an area or period where the first power having the first frequency is applied into the chamber 110, and then the first power having the first frequency and the second power having the second frequency are applied into the chamber 110 together. In example embodiments, the controller 600 may control such that there is the area or period in which the first power supplier 310 applies the first power and the second power supplier 320 applies the second power together when the reaction gas is applied into the chamber 110. Specifically, the substrate processing apparatus 100 may allow the first precursor supplier 410 to provide the metal precursor into the chamber 110 while applying the first power having the first frequency into the chamber 110, thereby forming the metal layer on the substrate 200. The substrate processing apparatus 100 may provide the reaction gas into the chamber 110 by the second precursor supplier 420 to oxidize or nitride the metal layer formed on the substrate 200 while having the area or period where the first power having the first frequency and the second power having the second frequency are applied into the chamber 110 together.

Although not illustrated in the drawing, in some other example embodiments, the substrate processing apparatus 100 may be configured such that there may be the area or period where the first power having the first frequency is applied into the chamber 110, and then the first power having the first frequency and the second power having the second frequency are applied into the chamber 110 together, and start points where the first power and the second power are applied may be different from each other. In example embodiments, the controller 600 may control such that there exists the area or period where the first power supplier 310 applies the first power and the second power supplier 320 applies the second power together when the reaction gas is applied into the chamber 110, and the start points where the first power and the second power are applied are different from each other.

In this case, for example, although not particularly limited, end points where the first power and the second power are applied may be the same.

Although not illustrated in the drawing, in some other example embodiments, the substrate processing apparatus 100 may be configured such that there may be the area or period where the first power having the first frequency is applied into the chamber 110, and then the first power having the first frequency and the second power having the second frequency are applied into the chamber 110 together, and end points where the first power and the second power are applied may be different from each other. In example embodiments, the controller 600 may control such that there exists the area or period where the first power supplier applies the first power and the second power supplier applies the second power together when the reaction gas is provided into the chamber 110, and the end points where the first power and the second power are applied are different from each other.

In this case, for example, although not particularly limited, the start points where the first power and the second power are applied may be the same.

Referring to FIG. 2, the second frequency of the second power may be greater than the first frequency of the first power, and the ratio F₂/F₁ of the second frequency F₂ and the first frequency F₁ may be, but is not limited to, 1.5 or greater to 500 or less, 1.6 or greater to 490 or less, 1.7 or greater to 480 or less, 1.8 or greater to 470 or less, 1.9 or greater to 460 or less, or 2 or greater to 450 or less. In example embodiments, the first frequency F₁ may be in a range of 100 kHz to 1,000 kHz, and the second frequency F₂ may be in a range of 2 MHz to 40 MHz. In example embodiments, the controller 600 may control the second frequency to be greater than the first frequency. In example embodiments, the controller 600 may control the ratio F₂/F₁ of the second frequency F₂ and the first frequency F₁ to satisfy the above-described range.

Referring to FIG. 3, the first frequency of the first power may be greater than the second frequency of the second power, and the ratio F₁/F₂ of the first frequency F₁ and the second frequency F₂ may be, but is not limited to, 1.5 or greater to 500 or less, 1.6 or greater to 490 or less, 1.7 or greater to 480 or less, 1.8 or greater to 470 or less, 1.9 or greater to 460 or less, or 2 or greater to 450 or less. Here, the first frequency F₁ may be in a range of 2 MHz to 40 MHz, and the second frequency F₂ may be in a range of 100 kHz to 1000 kHz. In example embodiments, the controller 600 may control the first frequency to be greater than the second frequency. In example embodiments, the controller 600 may control the ratio F₁/F₂ of the first frequency F₁ and the second frequency F₂ to satisfy the above-described range.

In example embodiments, a magnitude of the second power may be greater than that of the first power. Referring to FIGS. 2 to 4, the magnitude of the first power and the magnitude of the second power may each mean amplitude of a wavelength shown. In example embodiments, a ratio W₂/W₁ of a magnitude W₂ of the second power and a magnitude W₁ of the first power may be, for example, 1.5 or more to 10 or less, 1.6 or more to 9.9 or less, 1.7 or more to 9.8 or less, 1.8 or more to 9.7 or less, 1.9 or more to 9.6 or less, or 2 or more to 9.5 or less, but is not limited thereto. In example embodiments, the controller 600 may control the magnitude of the second power to be greater than that of the first power. In example embodiments, the ratio W₂/W₁ of the magnitude W₂ of the second power and the magnitude W₁ of the first power may be controlled to satisfy the above-described range.

In example embodiments, the magnitude of the first power and the magnitude of the second power may be each independently 10 watts (W) to 2,000 W, but are not limited thereto.

In example embodiments, the substrate processing apparatus 100 may form plasma for depositing the metal layer and plasma for oxidizing or nitriding the metal layer at different frequencies. In particular, when the second frequency for forming the plasma for oxidizing or nitriding the metal layer is higher than the first frequency for forming the plasma for depositing the metal layer, it may be easier to control the stress of the oxidized or nitrided metal layer depending on the magnitude of the power. In example embodiments, when forming the oxidized or nitrided metal layer through the substrate processing apparatus 100, by appropriately controlling the compressive stress and tensile stress of the oxidized or nitrided metal layer, it is possible to suppress the substrate 200 and other layers formed on the substrate 200 from being convexly or concavely bent. In this case, when forming the plasma at a higher frequency than when forming the metal layer to oxidize or nitride the metal layer, the range of stress of the oxidized or nitrided metal layer increases depending on the magnitude of the power. This may be related to the tendency for the change in density depending on the magnitude of the power to increase as the plasma is formed at a higher frequency. Since the stress of the oxidized or nitrided metal layer changes due to the change in density of the plasma, the stress of the oxidized or nitrided metal layer may be controlled over a wider range depending on the magnitude of the power, and as a result, it may be easier to control the stress of the substrate 200 on which the oxidized or nitrided metal layer is deposited.

Meanwhile, when the first frequency of forming the plasma for depositing the metal layer is higher than the second frequency of forming the plasma for oxidizing or nitriding the metal layer, the oxidized or nitrided metal layer manufactured through the substrate processing apparatus 100 may have better uniformity.

In example embodiments, the pressure of the chamber 110 when providing the metal precursor into the chamber 110 may be lower than that of the chamber 110 when providing the reaction gas into the chamber 110. In example embodiments, the controller 600 may control the pressure inside the chamber 110. The controller 600 may control the pressure inside the chamber 110 when providing the reaction gas into the chamber 110 to be greater than the pressure inside the chamber 110 when providing the metal precursor into the chamber 110.

In example embodiments, the pressure of the chamber 110 when providing the metal precursor or when providing the reaction gas may each independently be about 0.1 Torr to 50 Torr.

In example embodiments, the oxidized or nitrided metal layer may be formed on the substrate 200 through the substrate processing apparatus 100. In example embodiments, the nitrided metal layer may include titanium nitride (TiN). In example embodiments, the oxidized or nitrided metal layer may be a hard mask.

In example embodiments, the substrate processing apparatus 100 may include a reactant supplier or reactant supply 710 that supplies a reducing reactant. In example embodiments, when the metal precursor is provided into the chamber 110, the reactant supplier 710 may supply the reducing reactant into the chamber 110.

In example embodiments, the substrate processing apparatus 100 may include a pressure gauge 700 that measures the pressure inside the chamber. In example embodiments, the pressure gauge 700 may be operate through an electrical signal from the controller 600, which will be described below.

In example embodiments, the substrate processing apparatus 100 may include an outlet through which impure gases generated during the process are discharged to the outside. The outlet may include a valve, and the valve may operate through the electrical signal from the controller 600, which will be described below.

As described above, when the metal precursor is provided on the substrate 200 supported on the stage 210, the substrate processing apparatus 100 may form the plasma from the metal precursor to form the deposition film 110D on the surface 110S within the chamber. In example embodiments, when the reaction gas is provided on the substrate 200 supported on the stage 210, the substrate processing apparatus 100 may form plasma from the reaction gas to oxidize or nitridize the deposition film 110D deposited on the surface 110S within the chamber.

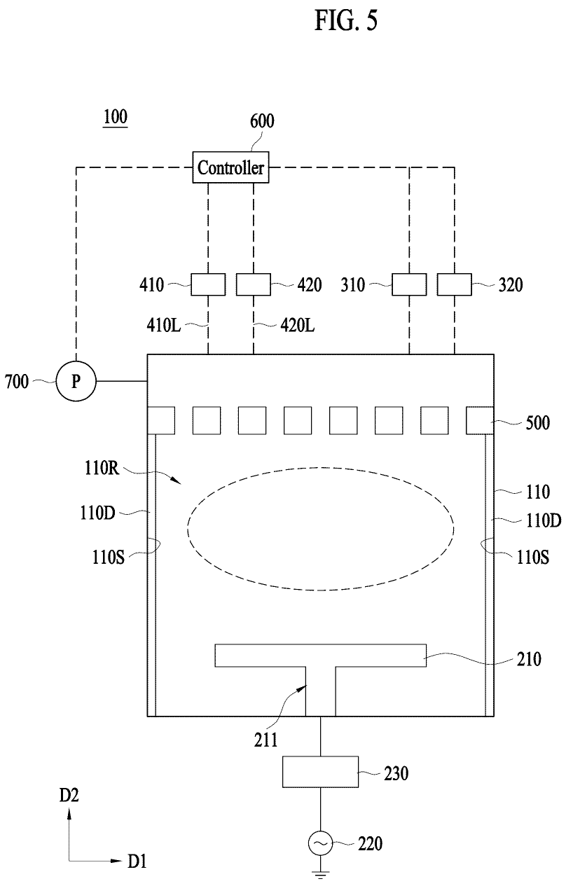

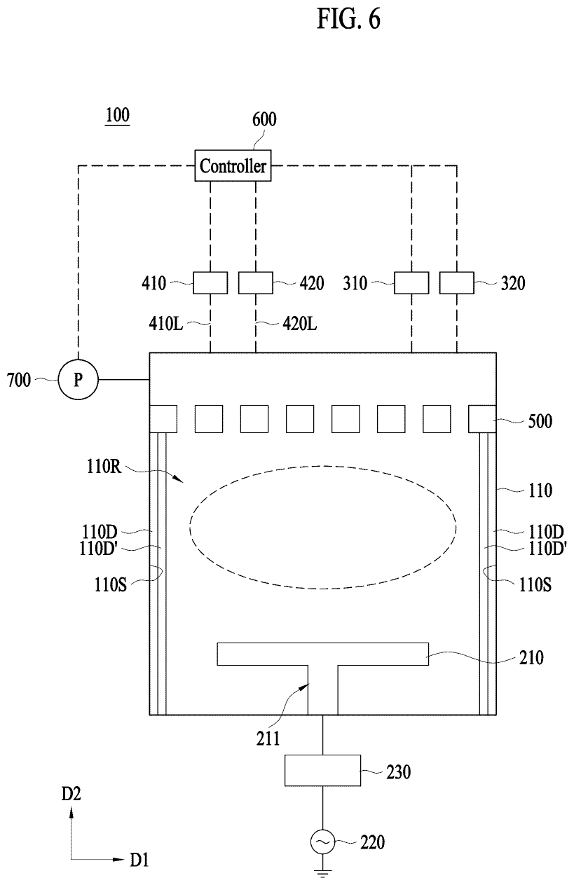

FIGS. 5 and 6 are cross-sectional views schematically illustrating the substrate processing apparatus 100 according to example embodiments of the present disclosure.

Referring to FIG. 5, the substrate 200 may be not supported on the stage 210. In example embodiments, the substrate 200 may not be supported on the stage 210 by removing the substrate 200 supported on the stage 210.

In example embodiments, the second power supplier 320 may apply the second power and the first precursor supplier 410 may provide the metal precursor into the chamber while the substrate 200 is not supported on the stage 210, and the first power supplier 310 may apply the first power and the second precursor supplier 420 may provide the reaction gas into the chamber while the substrate 200 is not supported on the stage 210.

Referring to FIG. 6, when the metal precursor is provided while the substrate 200 is not supported on the stage 210, a deposition film 110D′ may additionally be formed on the surface 110S within the chamber. In example embodiments, when the reaction gas is provided while the substrate 200 is not supported on the stage 210, the deposition film 110D′ additionally formed on the surface 110S within the chamber may be oxidized or nitrided.

By forming the deposition films 110D and 110D′ on the surface 110S within the chamber as described above, the stress and stability of the other deposition film previously formed on the surface 110S within the chamber may be improved, thereby preventing or delaying particles from falling off therefrom. As a result, the substrate processing apparatus 100 becomes easier to manage, thereby improving the overall process speed and yield.

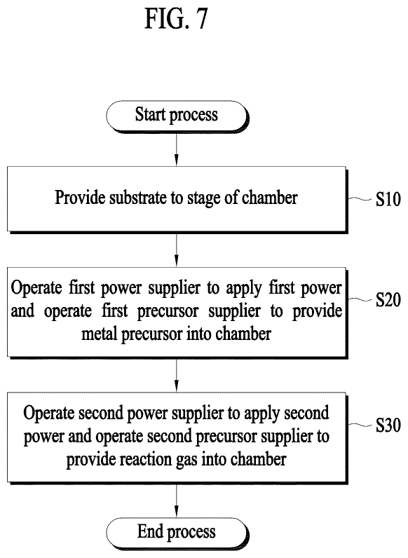

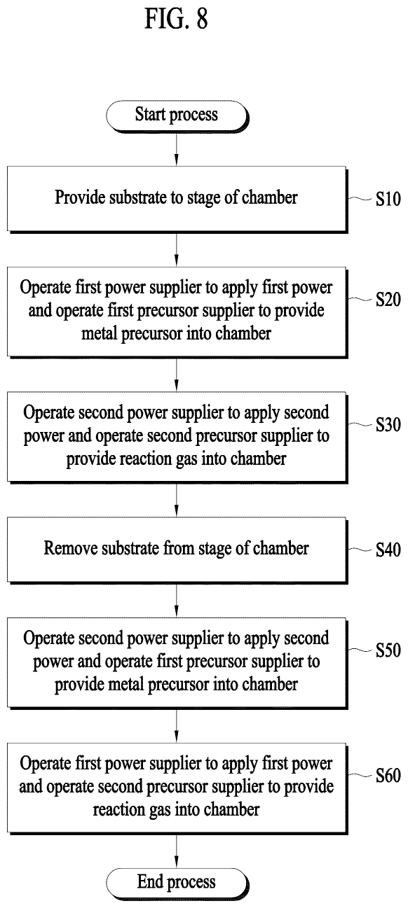

FIG. 7 is a flowchart for describing a method of performing a process of the substrate processing apparatus 100 according to example embodiments of the present disclosure. FIG. 8 is a flowchart for describing a method of performing a process of a substrate processing apparatus 100 according to example embodiments of the present disclosure.

In example embodiments, the controller 600 may control the first power supplier 310, the second power supplier 320, the first precursor supplier 410, and the second precursor supplier 420 as described above. In addition, the controller 600 may control to open the valve of the outlet if necessary to discharge impure gases generated during the deposition reaction to the outside.

Referring to FIG. 7, in example embodiments, the substrate 200 may be provided on the stage 210 (block S10). Thereafter, the controller 600 may operate the first power supplier 310 to apply the first power to the chamber 110, and operate the first precursor supplier 410 to provide the metal precursor onto the substrate 200 supported on the stage 210 (block S20). In this way, the plasma may be formed from the metal precursor provided by the first precursor supplier 410, and the metal layer may be formed on the substrate 200. The controller 600 may control the first power supplier 310 to control the magnitude and frequency of the power applied to the chamber 110.

Thereafter, the controller 600 may operate the second power supplier 320 to apply the second power into the chamber 110, and operate the second precursor supplier 420 to provide the reaction gas onto the substrate 200 supported on the stage 210 (block S30). In this way, the plasma may be formed from the reaction gas provided by the second precursor supplier 420, and the metal layer formed on the substrate 200 may be oxidized or nitrided. The controller 600 may control the second power supplier 320 to control the magnitude and frequency of the power applied to the chamber 110.

In example embodiments, the controller 600 may improve the poor patterning by controlling the deposition process as described above, so that the substrate 200 including the oxidized or nitrided metal layer may have a wide stress range.

Referring to FIG. 8, in example embodiments, the substrate 200 may be provided on the stage 210. In the method of performing the process of the substrate processing apparatus 100 according to other example embodiments, unless it is contradictory, the controller 600 may control the first power supplier 310, the second power supplier 320, the first precursor supplier 410, and the second precursor supplier 420, similarly to as described above. In this way, the plasma may be formed from the metal precursor or the reaction gas, and the deposition film may be formed on the substrate 200 and the surface 110S within the chamber with the plasma formed from the metal precursor, and the deposition film formed on the substrate 200 and the surface 110S within the chamber may be oxidized or nitrided with the plasma formed from the reaction gas.

Thereafter, the substrate 200 may be removed from the stage 210 of the chamber 110 (block S40). Thereafter, the controller 600 may operate the second power supplier 320 to apply the second power, and operate the first precursor supplier 410 to provide the metal precursor into the chamber 110 (block S50). In this way, the plasma may be formed. The controller 600 may control the second power supplier 320 to control the magnitude and frequency of the power applied to the chamber 110. From the formed plasma, the deposition film may be additionally formed on the surface 110S within the chamber.

Thereafter, the controller 600 may operate the first power supplier 310 to apply the first power, and operate the second precursor supplier 420 to provide the reaction gas into the chamber 110 (block S60). In this way, the plasma may be formed. The controller 600 may control the first power supplier 310 to control the magnitude and frequency of the power applied to the chamber 110. From the formed plasma, the deposition film additionally deposited on the surface 110S within the chamber may be oxidized or nitrided.

In example embodiments, when the controller 600 controls in this manner, the stability of the oxidized or nitrided deposition film formed on the surface 110S within the chamber may be improved, thereby preventing or delaying particles from falling off therefrom. As a result, the substrate processing apparatus 100 becomes easier to manage, thereby improving the overall process speed and yield.

Example embodiments of the present disclosure have been described hereinabove with reference to the accompanying drawings, but the present disclosure is not limited to the above-described example embodiments, and may be implemented in various different forms, and one of ordinary skill in the art to which the present disclosure pertains may understand that the present disclosure may be implemented in other specific forms without changing the technical spirit or essential features of the present disclosure. Therefore, it is to be understood that the example embodiments described above are illustrative rather than being restrictive in all aspects.

What is claimed is:

1. A substrate processing apparatus, comprising:
a chamber;
a stage in the chamber and configured to support a substrate;
a first precursor supplier configured to provide a metal precursor into the chamber;
a second precursor supplier configured to provide a reaction gas into the chamber;
a first power supplier configured to apply first power having a first frequency into the chamber;
a second power supplier configured to apply second power having a second frequency into the chamber; and
a controller configured to control the first power supplier to apply the first power and the first precursor supplier to provide the metal precursor into the chamber, and the second power supplier to apply the second power and the second precursor supplier to provide the reaction gas into the chamber,
wherein the first frequency and the second frequency are different.

2. The substrate processing apparatus of claim 1, wherein the controller controls the first power supplier, the first precursor supplier, the second power supplier, and the second precursor supplier such that the first power is applied and the metal precursor is provided into the chamber, and then the second power is applied and the reaction gas is provided into the chamber.

3. The substrate processing apparatus of claim 1, wherein the controller controls the first power supplier, the second power supplier, and the second precursor supplier such that there exists a period in which the first power supplier applies the first power and the second power supplier applies the second power together when the reaction gas is provided into the chamber.

4. The substrate processing apparatus of claim 3, wherein the controller controls the first power supplier, the second power supplier, and the second precursor supplier such that there exists the period in which the first power supplier applies the first power and the second power supplier applies the second power together when the reaction gas is provided into the chamber, and start points when the first power and the second power are applied are different from each other.

5. The substrate processing apparatus of claim 3, wherein the controller controls the first power supplier, the second power supplier, and the second precursor supplier such that there exists the period in which the first power supplier applies the first power and the second power supplier applies the second power together when the reaction gas is provided into the chamber, and end points of applying the first power and the second power are different from each other.

6. The substrate processing apparatus of claim 1, wherein the controller controls the first power supplier and the second power supplier such that a magnitude of the second power is greater than a magnitude of the first power.

7. The substrate processing apparatus of claim 6, wherein the controller controls the first power supplier and the second power supplier such that a ratio (W₂/W₁) of the magnitude (W₂) of the second power and the magnitude (W₁) of the first power is 1.5 or greater and 10 or less.

8. The substrate processing apparatus of claim 1, wherein the controller controls pressure inside the chamber, and
the controller controls the pressure inside the chamber when the reaction gas is provided into the chamber to be greater than the pressure inside the chamber when the metal precursor is provided into the chamber.

9. The substrate processing apparatus of claim 1, wherein the controller controls the first power supplier and the second power supplier such that the second frequency is greater than the first frequency.

10. The substrate processing apparatus of claim 9, wherein the controller controls the first power supplier and the second power supplier such that a ratio (F₂/F₁) of the second frequency (F₂) and the first frequency (F₁) is 1.5 or greater and 500 or less.

11. The substrate processing apparatus of claim 1, wherein the controller controls the first power supplier and the second power supplier such that the first frequency is greater than the second frequency.

12. The substrate processing apparatus of claim 11, wherein the controller controls the first power supplier and the second power supplier such that a ratio (F₁/F₂) of the first frequency (F₁) and the second frequency (F₂) is 1.5 or greater and 500 or less.

13. The substrate processing apparatus of claim 1, wherein the metal precursor contains a metal halide.

14. The substrate processing apparatus of claim 1, wherein the reaction gas includes at least one selected from the group consisting of nitrogen gas (N₂), ammonia gas (NH₃), oxygen gas (O₂), and diborane (B₂H₆).

15. The substrate processing apparatus of claim 1, further comprising:
a reactant supplier configured to supply a reducing reactant into the chamber,
wherein the controller controls the reactant supplier to supply the reducing reactant into the chamber when the metal precursor is provided into the chamber.

16. A substrate processing apparatus, comprising:
a chamber;
a stage in the chamber and configured to support a substrate;
a first precursor supplier configured to provide a metal precursor into the chamber;
a second precursor supplier configured to provide a reaction gas into the chamber;
a first power supplier configured to apply first power having a first frequency into the chamber;
a second power supplier configured to apply second power having a second frequency into the chamber; and
a controller configured to control the first power supplier to apply the first power and the first precursor supplier to provide the metal precursor onto the substrate supported on the stage, and the second power supplier to apply the second power and the second precursor supplier to provide the reaction gas onto the substrate supported on the stage,
wherein the first frequency and the second frequency are different.

17. The substrate processing apparatus of claim 16, wherein the controller controls the first power supplier, the first precursor supplier, the second power supplier, and the second precursor supplier such that the first power is applied and the metal precursor is provided onto the substrate supported on the stage, and then the second power is applied and the reaction gas is provided onto the substrate supported on the stage.

18. The substrate processing apparatus of claim 17, wherein the controller controls the second power supplier to apply the second power and the first precursor supplier to provide the metal precursor into the chamber while the substrate is not supported on the stage, and the first power supplier to apply the first power and the second precursor supplier to provide the reaction gas into the chamber while the substrate is not supported on the stage.

19. The substrate processing apparatus of claim 18, wherein the controller controls the first power supplier and the second power supplier such that the ratio (F₂/F₁) of the second frequency (F₂) and the first frequency (F₁) is 1.5 or greater and 500 or less.

20. A substrate processing apparatus, comprising:
a chamber;
a stage in the chamber and configured to support a substrate;
a first precursor supplier configured to provide a metal precursor into the chamber;
a second precursor supplier configured to provide a reaction gas into the chamber;
a first power supplier configured to apply first power having a first frequency into the chamber;
a second power supplier configured to apply second power having a second frequency into the chamber; and
a controller configured to control the first power supplier to apply the first power and the first precursor supplier to provide the metal precursor onto the substrate supported on the stage, and the second power supplier to apply the second power and the second precursor supplier to provide the reaction gas onto the substrate supported on the stage,
wherein the controller controls the first power supplier, the first precursor supplier, the second power supplier, and the second precursor supplier such that the first power is applied and the metal precursor is provided onto the substrate supported on the stage, and then the second power is applied and the reaction gas is provided onto the substrate supported on the stage,
the controller controls the second power supplier to apply the second power and the first precursor supplier to provide the metal precursor into the chamber while the substrate is not supported on the stage, and the first power supplier to apply the first power and the second precursor supplier to provide the reaction gas into the chamber while the substrate is not supported on the stage,
the controller controls the first power supplier and the second power supplier such that a ratio (F₂/F₁) of the second frequency (F₂) and the first frequency (F₁) is 1.5 or greater and 500 or less, and
the controller controls the first power supplier and the second power supplier such that a magnitude of the second power is greater than that of the first power.
